(19) United States
(12) Patent Application Publication
(10) Pub. No.: US 2010/0144403 A1
(43) Pub. Date: Jun. 10, 2010

(54) ISOLATED MONOLITHIC ELECTRIC POWER

(75) Inventor: Jean-Luc Morand, Tours (FR)

Correspondence Address: STMicroelectronics Inc.;c/o WOLF, GREENFIELD & SACKS, P.C., 600 Atlantic Avenue, BOSTON, MA, 02210-2206, US

(73) Assignee: STMICROELECTRONICS S.A., MONTROUGE (FR)

(21) Appl. No.: 12/593,967

(22) PCT Filed: Apr. 1, 2008
(86) PCT No.: PCT/FR08/50572

§ 371 Date: Feb. 11, 2010

(30) Foreign Application Priority Data
Apr. 2, 2007 (FR) 0754200

(51) Int. Cl. H04B 1/38; H01L 35/30

(52) U.S. Cl. 455/573; 136/205

(57) ABSTRACT

An isolated monolithic electrical converter including a substrate made of a resistive material, the underside of which has two input electrodes spaced apart from each other, constituting the primary, an insulating layer on the top side of the substrate, and, on the insulating layer, at least two elements made of respectively p-doped and n-doped semiconductor thermoelectric materials electrically connected in series, the ends of the series connection constituting the secondary of the converter.

### BACKGROUND OF THE INVENTION

1. Field of the Invention

The present invention relates to an electric converter capable of providing its secondary with a low-voltage D.C. electric power supply isolated from a power supply applied to its primary. The present invention especially aims at the case where the power supply applied to the primary is the A.C. mains voltage at 50 or 60 Hz. The converter will then be said to be a mains power supply.

The present invention also aims at the use of such a converter as a cell phone charger. Such converters will find many other applications, for example, for the supply of an electric household device programmer.

2. Discussion of the Related Art

One of the constraints required by a main power supply is that the secondary needs to be galvanically isolated from the primary. A mains power supply generally comprises a transformer which is its heaviest and most bulky element. This transformer is linked to an electronic circuit for rectifying the A.C. current, for example comprising a diode bridge, various resistive and capacitive elements, a zener-type diode for establishing a D.C. reference voltage as well as, possibly, transistors, thyristors, and/or triacs for the current or voltage stabilization.

Thus, generally, existing converters are not monolithic.

Further, due to their weight and to their bulk, conventional converters are difficult to incorporate into a portable device such as a cell phone.

A portable phone is generally provided with a rechargeable battery that the user only uses in mobile mode and is sold with a charger link to a lead to be connected, on the one hand to a power inlet of the portable device, on the other hand to the mains. The user of a cell phone needs to take along a charger which is often as bulky as his phone and may be heavier.

Up to now, there exist no low-bulk mains supply or charger which may be easily arranged in a cell phone or another small portable device such as a pocket computer, which also enables plugging the device to a mains outlet by means of a simple supply cable.

### SUMMARY OF THE INVENTION

An embodiment of the present invention provides an isolated monolithic electric converter comprising, on a substrate made of a resistive material having its lower surface having two input electrodes distant from each other forming a primary, an insulating layer, and at least two respectively P- and N-doped thermoelectric semiconductor elements electrically connected in series, the ends of the series connection forming the secondary of the converter.

According to an embodiment of the present invention, each thermoelectric element comprises a metallization on its upper surface and a metallization on its lower surface.

According to an embodiment of the present invention, the substrate is made of silicon.

According to an embodiment of the present invention, the first P-doped thermoelectric semiconductor element is formed of bismuth tellurium doped with antimony and the second N-doped thermoelectric semiconductor element is formed of bismuth tellurium doped with selenium.

According to an embodiment of the present invention, the converter comprises a plurality of thermoelectric cells series-connected with one another.

The foregoing and other objects, features, and advantages of the present invention will be discussed in detail in the following non-limiting description of specific embodiments in connection with the accompanying drawings.

### BRIEF DESCRIPTION OF THE DRAWINGS

FIG. 1 is a simplified view of an example of an isolated monolithic converter using thermoelectric elements according to an embodiment of the present invention;

FIG. 2 is a detailed cross-section view of an example of an isolated monolithic converter according to an embodiment of the present invention;

FIG. 3 is a cross-section view of the converter of FIG. 2 assembled on a support provided with a cooler; and

FIG. 4 shows different steps of a method for forming the converter of FIG. 2.

### DETAILED DESCRIPTION

For clarity, the same elements have been designated with the same reference numerals in the different drawings and, further, as usual in the representation of integrated circuits, the various drawings have not been drawn to scale.

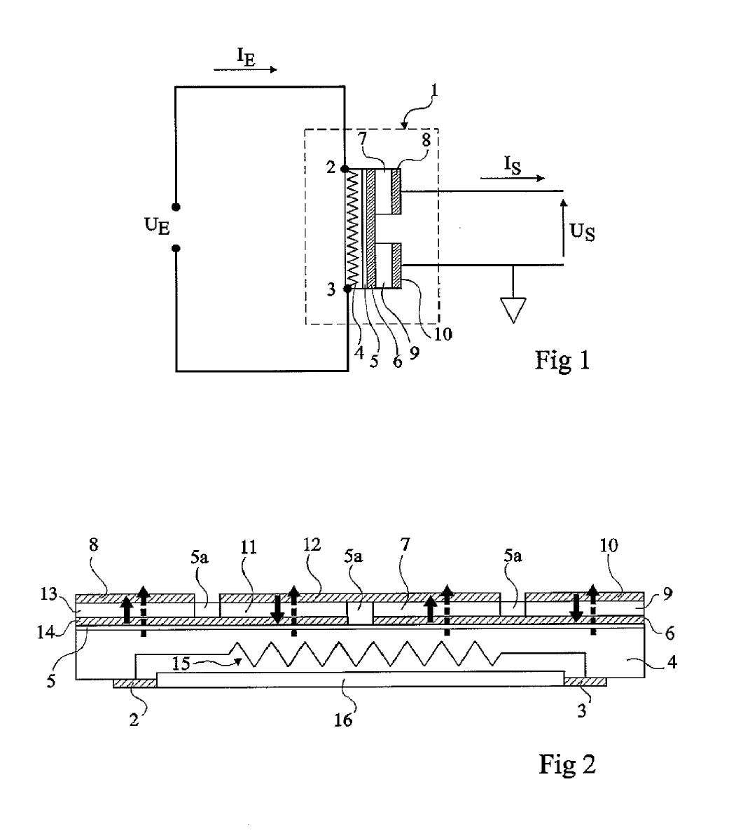

FIG. 1 illustrates an example of an isolated monolithic converter 1 supplied at its primary by an A.C. source voltage Ue and current Ie, and providing its secondary with a D.C. voltage Us and a current Is. Voltage Ue is applied between two terminals 2 and 3 of the rear surface of a silicon wafer 4. The front surface of silicon wafer 4 is covered with an electrically-insulating layer 5 which however is a good heat conductor. On layer 5, an electrode 6 electrically connects the lower surfaces of two thermoelectric elements formed of layers of N and P semiconductors (or vice-versa) 7 and 9, provided with electrodes 8 and 10 on their upper surfaces. Electrodes 8 and 10 form the output or secondary terminals of the power supply.

In operation, the silicon wafer that conducts a current sees its temperature rise by Joule effect. This temperature increase transmits through electrically-insulating layer 5 to electrode 6 and to the lower surfaces of thermoelectric elements 7 and 9. The temperature of electrodes 8 and 10 on the side of the opposite surfaces of thermoelectric elements 7 and 9 remains close to the ambient temperature. A D.C. voltage difference Us thus creates, by Seebeck effect, between electrodes 8 and 10 of series-connected thermoelectric elements 7 and 9 submitted to a temperature gradient. Electrodes 8 and 10 are thus capable of providing a D.C. current Is to a load not shown in the drawing. This load will for example be a battery. Various current and/or voltage regulation elements may be inserted between D.C. voltage source Us and the load.

FIG. 2 is an enlarged simplified cross-section view of another example of an isolated monolithic converter 1. The same elements as those of FIG. 1 have the same reference numerals. Conversely to FIG. 1 on which a single pair of thermoelectric elements is shown (one N element and one P element connected in series), FIG. 2 shows two pairs of thermoelectric elements 7-9 and 11-13, alternately N elements (9 and 11) and P elements (7 and 13). These elements are electrically connected in series. An electrode 6 connects the rear surfaces of elements 7 and 9, an electrode 12 connects the front surface of element 7 to the front surface of element 11, and an electrode 14 connects the rear surfaces of elements 11 and 13. The D.C. output voltage is available (in operation) between an electrode 10 on the front surface of element 9 and an element 8 on the front surface of element 13. Elements 7, 9, 11, and 13 are laterally insulated by an electrically insulating layer 5a which makes the upper surface of the device substantially planar, which especially eases the deposition of conductive layers on this upper surface. Insulating layer 5 which separates electrodes 6 and 14 of silicon substrate 4 is preferably made of a material which is both electrically insulating and thermally conductive to ensure a proper thermal coupling between substrate 4 and thermoelectric elements 7, 9, 11, and 13. Even if the material of insulating layer 5 is not a very good heat conductor, this layer will be selected to be thin enough to avoid substantially affecting the heat conduction between the substrate and the rear surfaces of the thermoelectric elements.

In FIG. 2, the arrows respectively illustrate the heat flow (arrows in dotted lines) and the direction of the voltage developing across each thermoelectric element when it is submitted to a temperature gradient (arrows in full lines).

Silicon substrate 4 is provided on its lower surface side with two primary current input electrodes 2 and 3. The lower surface portions not coated with electrodes 2 and 3 are preferably covered with an electrically-insulating layer 16 which may penetrate into the substrate. A resistor 15 has symbolically been shown between the two electrodes 2 and 3, thus schematizing the resistive flow of the A.C. current which causes the heating up of said substrate 4, which thus behaves as a hot reservoir for the thermoelectric elements (having their opposite surfaces at ambient temperature).

Two embodiments of an isolated monolithic converter 1 such as shown in FIG. 2 are given hereafter.

### EXAMPLE 1

In a first example of embodiment, the power supply primary receives the mains A.C. voltage Ue of 230 volts rms. at a 50-hertz frequency. The distance between electrodes 2 and 3, the thickness of silicon substrate 4, possibly adjusted by the penetration of electrically insulating layer 16, and the silicon doping are selected so that resistance 15 has a value Rp of 17.6 kΩ. The silicon conducts a 13-mA current Ip, which corresponds to a 3-watt total power dissipated at the primary.

Four thermoelectric elements, respectively N-doped 9 and 11 (for example, made of selenium-doped bismuth tellurium) and P-doped 7 and 13 (for example, made of antimony-doped bismuth tellurium) are used. Such elements conventionally have a 6% Seebeck conversion efficiency (the Seebeck conversion efficiency is the efficiency of the transformation by the thermoelectric elements of the thermal power available between the two hot and cold sources at the contact of these elements and the electric power recovered across the thermoelectric elements). For a 98% thermal coupling, a 5-volt voltage Us and a 35-mA current Is, that is, a total 0.18-watt power, are thus recovered at the secondary of this power supply between electrodes 10 and 14.

Such a result is obtained, for example, with a square chip with a side from approximately 1 to 10 mm and a thermoelectric material thickness from approximately 10 to 50 μm.

### EXAMPLE 2

In a second example of embodiment, the same elements and the same parameter values as in example 1 are used, except for the following modifications: the silicon substrate is sized so that resistance Rp is equal to 2.3 kΩ, whereby a 100-mA current Ip and a 23-watt power are obtained at the primary.

At the secondary, a 5-volt voltage and a 270-mA current are obtained for a total 1.3-watt power.

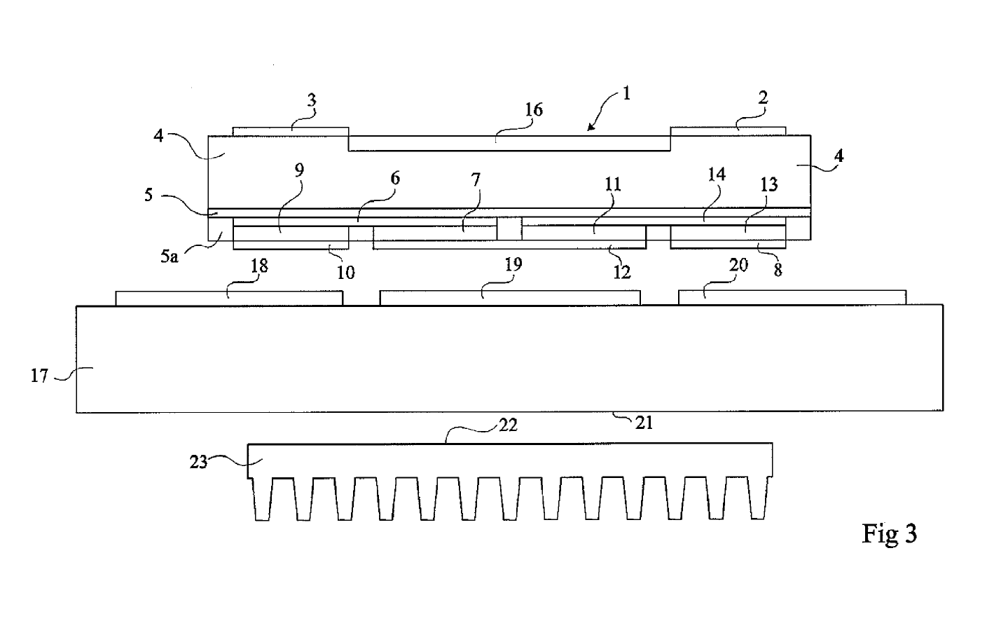

FIG. 3 shows an example of assembly of the structure of FIG. 2. The structure is turned over so that its electrodes 14, 8, and 10 respectively come into contact with metal electrodes 18, 19, and 20 arranged at the surface of a support 17 (electrode 19 being optional). Substrate 10 is made of a material which is both an electric insulator and a heat conductor, for example a ceramic. It may also be an electrically-conductive material (a metal) coated with a thin electrically-insulating layer on the side of structure 1. Lower surface 21 of support 17 preferably comes into contact with surface 22 of a sink 23 which enables maintaining the temperature of support 17 as close as possible to the desired temperature (cold source), for example, the ambient temperature. If no sink is used, support 17 may be a printed circuit board (PCB).

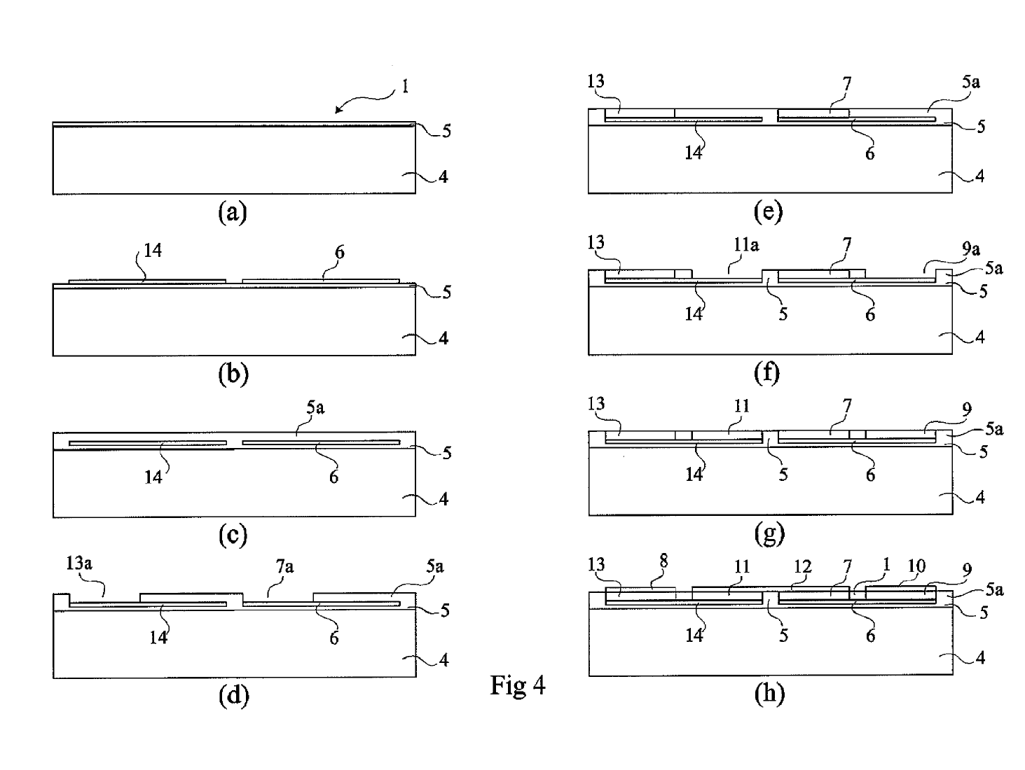

FIG. 4 illustrates successive steps of a possible embodiment of the isolated monolithic converter of FIG. 2.

On portions of a silicon wafer 4, an electrically insulating and thermally conductive uniform layer 5 (step a) are deposited, on which the two electrodes 6 and 14 are deposited to be distant from each other (step b), after which the assembly is covered with an insulating layer 5a (step c). Two openings 7a and 13a are then formed in layer 5a, respectively above openings 6 and 12 and partially exposing them (step d), after which the two, for example, P-doped thermoelectric layers 7 and 13 are deposited, respectively in openings 7a and 13a (step e). Two openings 9a, 11a are created again in layer 5a respectively above electrodes 6 and 12, which openings are respectively close to thermoelectric elements 7 and 13 (step f). A layer of an N-doped thermoelectric material, respectively 9 and 11 (step g) is then deposited in the openings. On the upper surface of element 1, there thus can successively be found in a horizontal plane an N element, a P element, an N element, followed by a P element, which are separated from one another by layer 5a which also surrounds them down to the ends of element 1. Finally, the upper surface of the thermoelectric elements is covered with electrodes which connect these elements in series: end electrode 10 covers element 9, electrode 8 electrically connects the two elements 7 and 11 while electrode 14 (on which the D.C. output voltage is recovered) covers the other end of element 13 (step h).

The different embodiments described hereabove are likely to have various alterations and modifications which will occur to those skilled in the art.

Resistive substrate 4 capable of being heated by Joule effect preferably is a single-crystal silicon wafer, since the associated manufacturing technologies have been widely developed in the context of the manufacturing of integrated circuits and of MEMS components. It should however be noted by those skilled in the art that other resistive substrates may be used.

The thermoelectric elements may be made of appropriately doped (N or P) bismuth tellurium. Other thermoelectric semiconductor materials such as, for example, lead tellurium, silicon-germanium, bismuth-antimony, etc. may be used provided that their figure of merit is sufficient in the temperature ranges at which this power supply is desired to be used (for example, for ambient temperatures from −40 to +80° C.). Indeed, the figure of merit of these materials is proportional to the Seebeck coefficient which characterizes the heat-to-current conversion of the element, and the higher the figure of merit, the greater the Seebeck coefficient of the material.

Insulating layer 5 initially deposited on substrate 4 will preferably be a thin silicon oxide layer when the substrate is made of silicon. A layer of a ceramic-type material may also be used.

Support 17 of element 1 may be any type of support capable of being metallized (electrode) and especially supports currently used in the art of printed circuit assembly, such as polyester, polyimide, PET, etc. Preferably, supports of ceramic type having a heat conduction generally greater than that of the above-mentioned plastic matters will be used.

It is also possible to connect a plurality of thermoelectric elements together since these elements are used in pairs (one P element and one N element connected in series). Such pairs may be connected together in series, parallel series, or parallel; they may be arranged in a line, as described, or according to any other desired geometric configuration.

The isolated monolithic converter described herein can be light and of low bulk. It can thus be incorporated in a cell phone to form the battery charger of this cell phone. The portable device can then be connected to an outlet by means of a simple electric wire.

According to an advantage of the present invention, the primary electric source only has to create a heating by Joule effect. It can thus be a D.C. or A.C. voltage, of any frequency (50 or 60 Hz).

Further, several sets of electrodes may be provided on the lower surface side to optimize the converter operation when different voltages, for example, 110 and 220 V, are applied to its primary.

Of course, the present invention is likely to have various alterations, modifications, and improvements which will readily occur to those skilled in the art. Such alterations, modifications, and improvements are intended to be part of this disclosure, and are intended to be within the spirit and the scope of the present invention. Accordingly, the foregoing description is by way of example only and is not intended to be limiting. The present invention is limited only as defined in the following claims and the equivalents thereto.

What is claimed is:

1. An isolated monolithic electric converter comprising, on a substrate made of a resistive material having its lower surface comprising two input electrodes distant from each other forming a primary:
an insulating layer, and
at least two respectively P- and N-doped thermoelectric semiconductor elements electrically connected in series, the ends of the series connection forming the secondary of the converter.

2. The converter of claim 1, wherein each thermoelectric element comprises a metallization on its upper surface and a metallization on its lower surface.

3. The converter of claim 1, wherein the substrate is made of silicon.

4. The converter of claim 1, wherein the first P-doped thermoelectric semiconductor element is formed of bismuth tellurium doped with antimony and the second N-doped thermoelectric semiconductor element is formed of bismuth tellurium doped with selenium.

5. The converter of claim 1, comprising a plurality of thermoelectric cells series-connected to one another.

6. A cell phone provided with the converter of any of the foregoing claims.
